(19) United States
(12) Patent Application Publication
(10) Pub. No.: US 2013/0009311 A1
(43) Pub. Date: Jan. 10, 2013

(54) SEMICONDUCTOR CARRIER, PACKAGE AND FABRICATION METHOD THEREOF

(75) Inventors: Pang-Chun Lin, Taichung (TW); Yueh-Ying Tsai, Taichung (TW); Yong-Liang Chen, Taichung (TW)

(73) Assignee: Siliconware Precision Industries Co., Ltd., Taichung (TW)

(21) Appl. No.: 13/308,938

(22) Filed: Dec. 1, 2011

(30) Foreign Application Priority Data
Jul. 8, 2011 (TW) 100124166

(51) Int. Cl. H01L 23/498; H01L 21/78; H01L 21/60; H01L 21/56

(52) U.S. Cl. 257/762; 257/766; 438/121; 438/113; 438/118; 257/E23.072; 257/E21.502; 257/E21.599; 257/E21.506

(57) ABSTRACT

A semiconductor package includes: a first encapsulant having tapered through holes each having a wide top and a narrow bottom; tapered electrical contacts disposed in the tapered through holes; circuits disposed on a top surface of the first encapsulant and each having one end connecting one of the electrical contacts and the other end having a bonding pad disposed thereon such that the bonding pads are circumferentially arranged to define a die attach area on the top surface of the first encapsulant. As such, a semiconductor chip can be disposed on the top surface of the first encapsulant in the die attach area and electrically connected to the bonding pads through conductive elements, and further a second encapsulant encapsulates the semiconductor chip, the conductive elements, the circuits and the first encapsulant so as to prevent falling off of the electrical contacts and reduce the length of the conductive elements.

### BACKGROUND OF THE INVENTION

1. Field of the Invention

The present invention relates to a semiconductor carrier, a semiconductor package and a fabrication method thereof.

2. Description of Related Art

A QFN (Quad Flat Non-leaded) semiconductor package generally has a die attach pad and a plurality of leads exposed through a bottom surface of the encapsulant thereof. The QFN semiconductor package can be mounted on a printed circuit board through surface mount technology (SMT) so as to form a circuit module having certain functions.

FIG. 1 is a cross-sectional view of a conventional QFN semiconductor package as disclosed by U.S. Pat. No. 6,635,957, U.S. Pat. No. 6,872,661, U.S. Pat. No. 7,009,286, U.S. Pat. No. 7,081,403 and U.S. Pat. No. 7,371,610. Referring to FIG. 1, a carrier 10 is provided. A plurality of through holes 100 having a certain diameter are formed in the carrier 10 and electroplated so as to form a plurality of electrical contacts 11. Therein, the electrical contacts 11 are formed by stacking different kinds of metals. Thereafter, a semiconductor chip 12 is disposed on the carrier 10 and electrically connected to the electrical contacts 11 through wire bonding. Finally, an encapsulant 13 is formed to encapsulate the semiconductor chip 12, the electrical contacts 11 and the carrier 10.

The conventional QFN semiconductor package is easy to fabricate and the electrical contacts thereof have small size. However, the electrical contacts are easy to fall off from the through holes. Further, since portions of the electrical contacts are distant from the semiconductor chip, long bonding wires such as long gold wires are needed, thus increasing the overall fabrication cost.

Therefore, it is imperative to overcome the above-described drawbacks.

### SUMMARY OF THE INVENTION

Accordingly, the present invention provides a semiconductor carrier, which comprises: a first encapsulant having opposite top and bottom surfaces and a plurality of tapered through holes penetrating the top and bottom surfaces and each having a wide top and a narrow bottom; a plurality of electrical contacts disposed in the tapered through holes and having corresponding tapered shapes; and a plurality of circuits disposed on the top surface of the first encapsulant and each having one end connecting one of the electrical contacts and the other end having a bonding pad disposed thereon such that the bonding pads are circumferentially arranged to define a die attach area on the top surface of the first encapsulant.

The present invention further provides a semiconductor package, which comprises: a first encapsulant having opposite top and bottom surfaces and a plurality of tapered through holes penetrating the top and bottom surfaces and each having a wide top and a narrow bottom; a plurality of electrical contacts disposed in the tapered through holes and having corresponding tapered shapes; a plurality of circuits disposed on the top surface of the first encapsulant and each having one end connecting one of the electrical contacts and the other end having a bonding pad disposed thereon such that the bonding pads are circumferentially arranged to define a die attach area on the top surface of the first encapsulant; a semiconductor chip disposed on the top surface of the first encapsulant in the die attach area; a plurality of conductive elements electrically connecting the semiconductor chip and the bonding pads; and a second encapsulant encapsulating the semiconductor chip, the conductive elements, the circuits and the first encapsulant.

The present invention further provides a fabrication method of a semiconductor carrier, which comprises the steps of: forming a first encapsulant on a carrier plate; forming a plurality of tapered through holes each having a wide top and a narrow bottom in the first encapsulant for exposing portions of the carrier plate; and forming a plurality of tapered electrical contacts in the tapered through holes, respectively, and forming a plurality of circuits on the first encapsulant, wherein each of the circuits has one end connecting one of the electrical contacts and the other end having a bonding pad formed thereon such that the bonding pads are circumferentially arranged to define a die attach area on the first encapsulant.

The present invention further provides a fabrication method of a semiconductor package, which comprises the steps of: forming a first encapsulant on a carrier plate; forming a plurality of tapered through holes each having a wide top and a narrow bottom in the first encapsulant for exposing portions of the carrier plate; forming a plurality of tapered electrical contacts in the tapered through holes, respectively, and forming a plurality of circuits on the first encapsulant, wherein each of the circuits has one end connecting one of the electrical contacts and the other end having a bonding pad formed thereon such that the bonding pads are circumferentially arranged to define a die attach area on the first encapsulant; disposing a semiconductor chip on the first encapsulant in the die attach area; forming a plurality of conductive elements for electrically connecting the semiconductor chip and the bonding pads; forming a second encapsulant to encapsulate the semiconductor chip, the conductive elements, the circuits and the first encapsulant; and removing the carrier plate to expose the electrical contacts through a bottom surface of the first encapsulant.

Therefore, by forming in the first encapsulant a plurality of tapered through holes each having a wide top and a narrow bottom, the present invention prevents electrical contacts subsequently formed in the tapered through holes from falling off from the tapered through holes, thus increasing the reliability of the semiconductor package. Further, by forming a plurality of circuits on the first encapsulant and each having one end connecting one of the electrical contacts and the other end having a bonding pad disposed thereon, the present invention facilitates the wire bonding process and effectively reduces the length of the conductive elements, thereby reducing the overall fabrication cost.

### BRIEF DESCRIPTION OF DRAWINGS

FIG. 1 is a cross-sectional view of a conventional QFN semiconductor package; and

FIGS. 2A to 2L are cross-sectional views showing a semiconductor carrier, a semiconductor package and a fabrication method thereof according to the present invention, wherein FIG. 2F′ is a top view of portions of FIG. 2F.

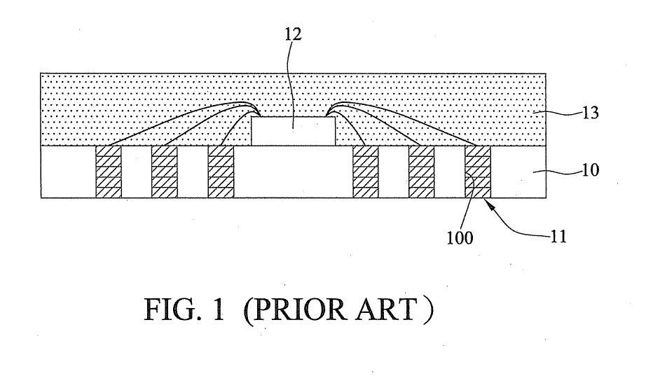

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “one”, “above”, etc. are merely for illustrative purpose and should not be construed to limit the scope of the present invention.

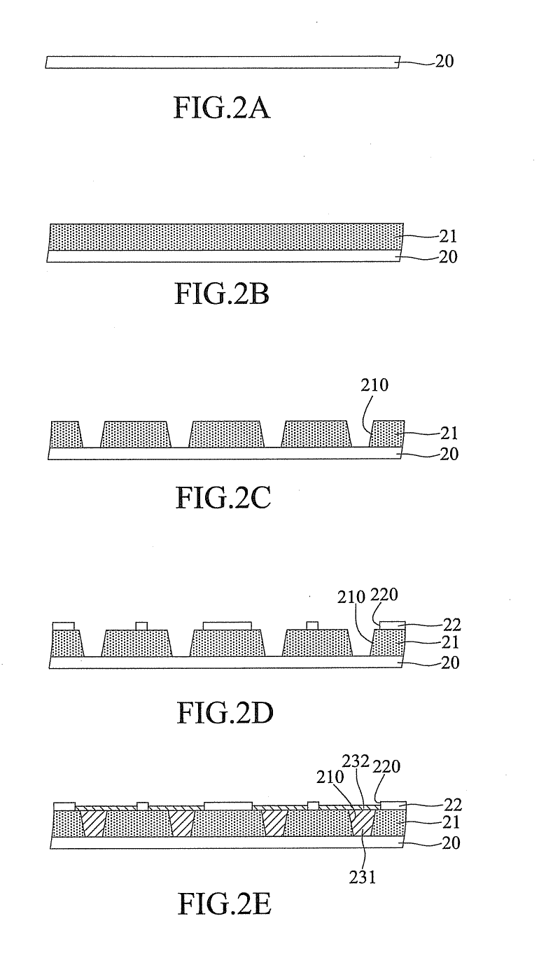

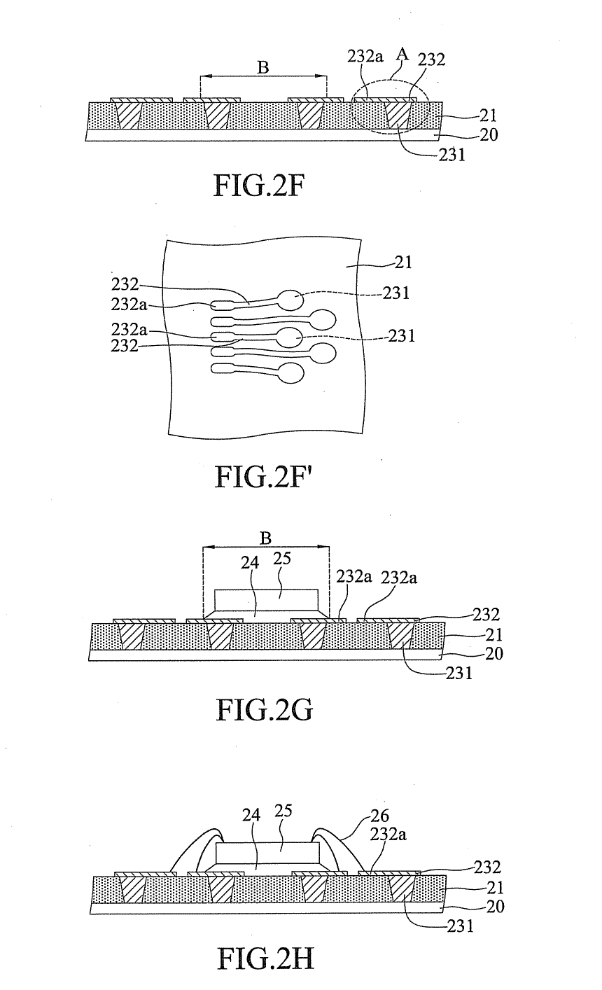

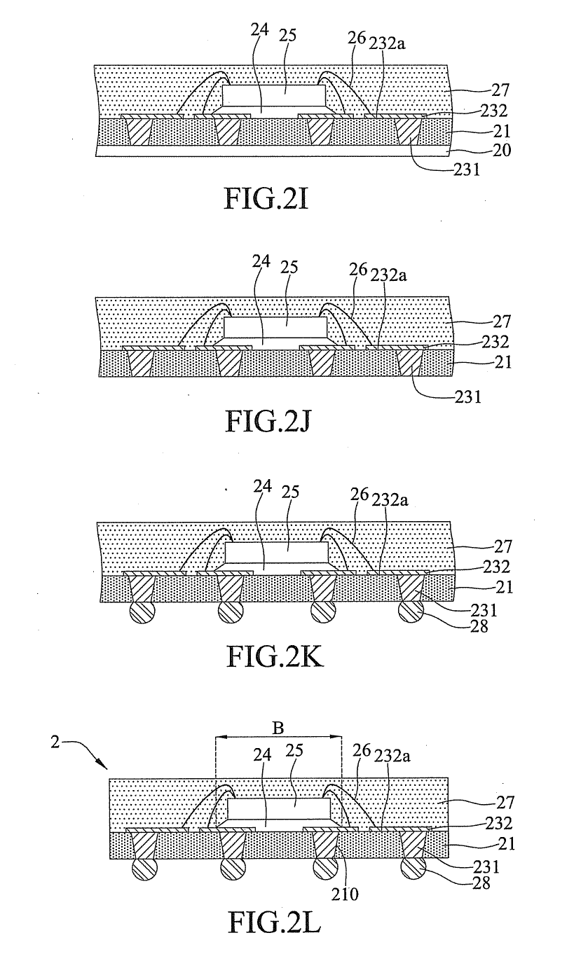

FIGS. 2A to 2L are cross-sectional views showing a semiconductor carrier, a semiconductor package and a fabrication method thereof according to the present invention. Therein, FIG. 2F′ is a top view of portions of FIG. 2F.

Referring to FIG. 2A, a carrier plate 20 is prepared.

Referring to FIG. 2B, a first encapsulant 21 is formed on the carrier plate 20.

Referring to FIG. 2C, a plurality of tapered holes 210 each having a wide top and a narrow bottom are formed in the first encapsulant 21 through laser drilling or mechanical drilling, thereby exposing portions of the carrier plate 20.

Referring to FIG. 2D, a resist layer 22 is formed on the first encapsulant 21 and a plurality of openings 220 are formed in the resist layer 22 for exposing the tapered through holes 210 and portions of the first encapsulant 21.

Referring to FIG. 2E, a plurality of electrical contacts 231 are formed in the tapered holes 210 exposed through the openings 220 of the resist layer 22, and a plurality of circuits 232 are formed on the electrical contacts 231 and the first encapsulant 21 in the openings 220 of the resist layer 22. It should be noted that the electrical contacts 231 and the circuits 232 can be formed integrally. Alternatively, the electrical contacts 231 and the circuits 232 can be formed separately. That is, the electrical contacts 231 are formed first and then the circuits 232 are formed. Since related techniques are well known in the art, detailed description thereof is omitted herein.

Referring to FIGS. 2F and 2F′, the resist layer 22 is removed. Each of the circuits 232 has one end connecting one of the electrical contacts 231 and the other end having a bonding pad 232a formed thereon such that the bonding pads 232a are circumferentially arranged to define a die attach area B on the first encapsulant 21. FIG. 2F′ is a top view of an area A of FIG. 2F.

Through the above-described fabrication steps, a semiconductor carrier is obtained.

In another embodiment, the carrier plate 20 can be removed so as to form a semiconductor carrier without a carrier plate. Since related techniques are well known in the art, detailed description thereof is omitted herein.

Referring to FIG. 2G, a semiconductor chip 25 is disposed on the first encapsulant 21 in the die attach area B through an adhesive layer 24.

Referring to FIG. 2H, a plurality of conductive elements 26 such as metal wires are formed for electrically connecting the semiconductor chip 25 and the bonding pads 232a.

Referring to FIG. 2I, a second encapsulant 27 is formed to encapsualte the semiconductor chip 25, the conductive elements 26, the circuits 232 and the first encapsulant 21.

Referring to FIG. 2J, the carrier plate 20 is removed for exposing the electrical contacts 231 through a bottom surface of the first encapsulant 21.

Referring to FIG. 2K, a plurality of solder balls 28 are formed on the electrical contacts 231 exposed through the bottom surface of the encapsulant 21, respectively.

Referring to FIG. 2L, a singulation process is performed to obtain a plurality of QFN semiconductor packages 2.

The present invention further provides a semiconductor carrier, which has: a first encapsulant 21 having opposite top and bottom surfaces and a plurality of tapered through holes 210 penetrating the top and bottom surfaces and each having a wide top and a narrow bottom; a plurality of electrical contacts 231 disposed in the tapered through holes 210 and having corresponding tapered shapes; and a plurality of circuits 232 disposed on the top surface of the first encapsulant 21 and each having one end connecting one of the electrical contacts 231 and the other end having a bonding pad 232a disposed thereon such that the bonding pads 232a are circumferentially arranged to define a die attach area B on the top surface of the first encapsulant 21.

The above-described semiconductor carrier can further have a carrier plate 20 disposed on the bottom surface of the first encapsulant 21.

The electrical contacts 231 can be made of Au/Pd/Ni/Pd, Au/Ni/Cu/Ni/Au, Au/Ni/Cu/Ni/Ag, Au/Ni/Cu/Ag, Pd/Ni/Pd, Au/Ni/Au or Pd/Ni/Au layers in sequence.

The electrical contacts and the circuits can be formed integrally or separately.

The present invention further provides a semiconductor package 2, which has: a first encapsulant 21 having opposite top and bottom surfaces and a plurality of tapered through holes 210 penetrating the top and bottom surfaces and each having a wide top and a narrow bottom; a plurality of electrical contacts 231 disposed in the tapered through holes 210 and having corresponding tapered shapes; a plurality of circuits 232 disposed on the top surface of the first encapsulant 21 and each having one end connecting one of the electrical contacts 231 and the other end having a bonding pad 232a disposed thereon such that the bonding pads 232a are circumferentially arranged to define a die attach area B on the top surface of the first encapsulant 21; a semiconductor chip 25 disposed on the top surface of the first encapsulant 21 in the die attach area B; a plurality of conductive elements 26 electrically connecting the semiconductor chip 25 and the bonding pads 232a; and a second encapsulant 27 encapsulating the semiconductor chip 25, the conductive elements 26, the circuits 232 and the first encapsulant 21.

The above-described semiconductor package 2 can further have a plurality of solder balls 28 disposed on the electrical contacts 231 exposed through the bottom surface of the first encapsulant 21.

The above-described semiconductor package 2 can further have an adhesive layer 24 disposed between the semiconductor chip 25 and the first encapsulant 21. The adhesive layer 24 can be made of glass frit, an epoxy resin or a dry film.

In the above-described semiconductor package 2, the electrical contacts 231 can be made of Au/Pd/Ni/Pd, Au/Ni/Cu/Ni/Au, Au/Ni/Cu/Ni/Ag, Au/Ni/Cu/Ag, Pd/Ni/Pd, Au/Ni/Au or Pd/Ni/Au layers in sequence.

In the above-described semiconductor package 2, the electrical contacts and the circuits can be formed integrally or separately.

Therefore, by forming in the first encapsulant a plurality of tapered through holes each having a wide top and a narrow bottom, the present invention prevents electrical contacts subsequently formed in the tapered through holes from falling off from the tapered through holes, thus increasing the reliability of the semiconductor package. Further, since a plurality of circuits are disposed on the first encapsulant and each having one end connecting one of the electrical contacts and the other end having a bonding pad disposed close to the semiconductor chip, the conductive elements can connect the semiconductor chip and the bonding pads close to the semiconductor chip instead of connecting the semiconductor chip and the electrical contacts distant from the semiconductor chip, thereby effectively reducing the length of the conductive elements and reducing the overall fabrication cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor carrier, comprising:
a first encapsulant having opposite top and bottom surfaces and a plurality of tapered through holes penetrating the top and bottom surfaces and each having a wide top and a narrow bottom;
a plurality of electrical contacts disposed in the tapered through holes and having corresponding tapered shapes; and
a plurality of circuits disposed on the top surface of the first encapsulant and each having one end connecting one of the electrical contacts and the other end having a bonding pad disposed thereon such that the bonding pads are circumferentially arranged to define a die attach area on the top surface of the first encapsulant.

2. The carrier of claim 1, further comprising a carrier plate disposed on the bottom surface of the first encapsulant.

3. The carrier of claim 1, wherein the electrical contacts are made of Au/Pd/Ni/Pd, Au/Ni/Cu/Ni/Au, Au/Ni/Cu/Ni/Ag, Au/Ni/Cu/Ag, Pd/Ni/Pd, Au/Ni/Au or Pd/Ni/Au layers in sequence.

4. The carrier of claim 1, wherein the electrical contacts and the circuits are formed integrally or separately.

5. A semiconductor package, comprising:
a first encapsulant having opposite top and bottom surfaces and a plurality of tapered through holes penetrating the top and bottom surfaces and each having a wide top and a narrow bottom;
a plurality of electrical contacts disposed in the tapered through holes and having corresponding tapered shapes;
a plurality of circuits disposed on the top surface of the first encapsulant and each having one end connecting one of the electrical contacts and the other end having a bonding pad disposed thereon such that the bonding pads are circumferentially arranged to define a die attach area on the top surface of the first encapsulant;
a semiconductor chip disposed on the top surface of the first encapsulant in the die attach area;
a plurality of conductive elements electrically connecting the semiconductor chip and the bonding pads; and
a second encapsulant encapsulating the semiconductor chip, the conductive elements, the circuits and the first encapsulant.

6. The package of claim 5, further comprising a plurality of solder balls disposed on the electrical contacts exposed through the bottom surface of the first encapsulant.

7. The package of claim 5, further comprising an adhesive layer disposed between the semiconductor chip and the first encapsulant.

8. The package of claim 7, wherein the adhesive layer is made of glass frit, an epoxy resin or a dry film.

9. The package of claim 5, wherein the electrical contacts are made of Au/Pd/Ni/Pd, Au/Ni/Cu/Ni/Au, Au/Ni/Cu/Ni/Ag, Au/Ni/Cu/Ag, Pd/Ni/Pd, Au/Ni/Au or Pd/Ni/Au layers in sequence.

10. The package of claim 5, wherein the electrical contacts and the circuits are formed integrally or separately.

11. A fabrication method of a semiconductor carrier, comprising the steps of:
forming a first encapsulant on a carrier plate;
forming a plurality of tapered through holes each having a wide top and a narrow bottom in the first encapsulant for exposing portions of the carrier plate; and
forming a plurality of tapered electrical contacts in the tapered through holes, respectively, and forming a plurality of circuits on the first encapsulant, wherein each of the circuits has one end connecting one of the electrical contacts and the other end having a bonding pad formed thereon such that the bonding pads are circumferentially arranged to define a die attach area on the first encapsulant.

12. The method of claim 11, further comprising the step of removing the carrier plate.

13. The method of claim 11, wherein said forming the electrical contacts and the circuits comprises the steps of:
forming on the first encapsulant a resist layer having a plurality of openings for exposing the tapered through holes and portions of the first encapsulant;
forming the electrical contacts and the circuits in the openings of the resist layer; and
removing the resist layer.

14. The method of claim 11, wherein the electrical contacts are made of Au/Pd/Ni/Pd, Au/Ni/Cu/Ni/Au, Au/Ni/Cu/Ni/Ag, Au/Ni/Cu/Ag, Pd/Ni/Pd, Au/Ni/Au or Pd/Ni/Au layers in sequence.

15. The method of claim 11, wherein the tapered through holes are formed by laser drilling or mechanical drilling.

16. The method of claim 11, wherein the electrical contacts and the circuits are formed integrally or separately.

17. A fabrication method of a semiconductor package, comprising the steps of:
forming a first encapsulant on a carrier plate;
forming a plurality of tapered through holes each having a wide top and a narrow bottom in the first encapsulant for exposing portions of the carrier plate;
forming a plurality of tapered electrical contacts in the tapered through holes, respectively, and forming a plurality of circuits on the first encapsulant, wherein each of the circuits has one end connecting one of the electrical contacts and the other end having a bonding pad formed thereon such that the bonding pads are circumferentially arranged to define a die attach area on the first encapsulant;
disposing a semiconductor chip on the first encapsulant in the die attach area;
forming a plurality of conductive elements for electrically connecting the semiconductor chip and the bonding pads;
forming a second encapsulant to encapsulate the semiconductor chip, the conductive elements, the circuits and the first encapsulant; and
removing the carrier plate to expose the electrical contacts through a bottom surface of the first encapsulant.

18. The method of claim 17, wherein said forming the electrical contacts and the circuits comprises the steps of:
forming on the first encapsulant a resist layer having a plurality of openings for exposing the tapered through holes and portions of the first encapsulant;
forming the electrical contacts and the circuits in the openings of the resist layer; and
removing the resist layer.

19. The method of claim 17, further comprising forming a plurality of solder balls on the electrical contacts exposed through the bottom surface of the first encapsulant.

20. The method of claim 17, further comprising performing a singulation process.

21. The method of claim 19, further comprising performing a singulation process.

22. The method of claim 17, wherein the semiconductor chip is disposed on the first encapsulant through an adhesive layer.

23. The method of claim 22, wherein the adhesive layer is made of glass frit, an epoxy resin or a dry film.

24. The method of claim 17, wherein the electrical contacts are made of Au/Pd/Ni/Pd, Au/Ni/Cu/Ni/Au, Au/Ni/Cu/Ni/Ag, Au/Ni/Cu/Ag, Pd/Ni/Pd, Au/Ni/Au or Pd/Ni/Au layers in sequence.

25. The method of claim 17, wherein the tapered through holes are formed by laser drilling or mechanical drilling.

26. The method of claim 17, wherein the electrical contacts and the circuits are formed integrally or separately.
